(19) United States
(12) Patent Application Publication
(10) Pub. No.: US 2005/0118830 A1
(43) Pub. Date: Jun. 2, 2005

(54) Method of processing a workpiece

(76) Inventors: Nicholas John Appleyard, Bristol (GB); David Andrew Tossell, Bristol (GB); Matthew Peter Martin, Wiltshire (GB)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/997,886

(22) Filed: Nov. 29, 2004

Related U.S. Application Data
(60) Provisional application No. 60/528,215, filed on Dec. 10, 2003.

(30) Foreign Application Priority Data
Nov. 29, 2003 (GB) 0327785.2

(51) Int. Cl. H01L 21/302; H01L 21/461

(52) U.S. Cl. 438/720

(57) ABSTRACT

A method of processing a workpiece in a chamber with a reactive gas supplied to the chamber creating a chamber pressure including positioning the workpiece on a support in the chamber with a first face exposed to the reactive gas, supplying a non-reactive gas between the support and a second face of the workpiece, and controlling the differential gas pressure across the thickness of the workpiece.

### CROSS REFERENCE TO RELATED APPLICATION(S)

A claim to priority is made to U.S. Provisional Application Ser. No. 60/528,215, filed Dec. 10, 2003 and to British Patent Application No. 0327785.2 filed Nov. 29 2003.

### BACKGROUND OF THE INVENTION

1. Field of the Invention

This invention relates to a method of processing a workpiece in a chamber with a reactive gas supplied to the chamber creating a chamber pressure.

2. Background of the Invention

Both in the fields of the manufacture of semi-conductor devices and in micro-machining processes it is known to expose a workpiece to a reactive gas, which creates a pressure in the process chamber. Some reactions which occur are exothermic and cause the workpiece to be heated or the workpiece may be heated by a related process, e.g. ion bombardment. For this reason it is known to flow helium gas behind the workpiece to cool it and additionally or alternatively such non-reactive gas may be used to purge the backside of the workpiece to stop reactive gas attacking it.

### SUMMARY OF THE INVENTION

From one aspect the invention consists in a method of processing a workpiece in a chamber with a reactive gas supplied to the chamber creating a chamber pressure including:
positioning the workpiece on a support in the chamber with a first face exposed to the reactive gas;
supplying a non-reactive gas between the support and a second face of the workpiece; and
controlling the differential gas pressure across the thickness of the workpiece.

The applicants have appreciated that the prior art procedures were flawed, because they did not take into account variations in chamber pressure. This could lead to a reversal of the pressure gradient a round the edge of the workpiece, allowing reactive gas to flow behind the workpiece and/or a sudden change in the pressure gradient across the workpiece causing thin films formed in the workpiece, for example by the reactive gas process, to rupture spoiling an entire wafer of devices.

It is not always possible, in prior art procedures, to increase the non-reactive gas pressure sufficiently to guarantee a positive differential pressure at all times, as the maximum differential pressure, during variations in chamber pressure, may exceed the weight of the workpiece, which typically exerts a downwards pressure of the order of 10 Pa. This would lift the workpiece from the workpiece support and if additional clamping means are employed to prevent this, the maximum differential pressure cannot be allowed to exceed the clamping pressure, which is typically limited to 4 kPa with an electrostatic chuck, due to the risk of dielectric breakdown.

This situation can be well illustrated by reference to FIG. 1 which shows a prior art configuration in which a workpiece 1 sits on a workpiece support 2 within a process chamber 3. Reactive gas can be introduced at 9 and pumped out at 10 and cooling non-reactive gas can be introduced through the valve 13.

Turning to FIG. 2 it will be seen that the non-reactive gas is generally maintained at a constant pressure. In the graph shown in FIG. 2(a) the chamber pressure may at times be below the non-reactive gas pressure, in which case reactive gas will not get behind the workpiece, but at other times in the process, the chamber pressure will exceed the non-reactive gas pressure leading to the negative pressure gradient mentioned above. In FIG. 2(b), where the non-reactive gas pressure is relatively high with respect to the chamber pressure, the variations in chamber pressure during processing can cause substantial variations in the pressure drop across the workpiece leading to the pressure differential exceeding the pressure of clamping of the workpiece to the workpiece support, or a rupture of film as the process comes towards an end.

The applicants' new appreciation of what is occurring in the prior art apparatus has led them to control the differential gas pressure across the workpiece, with the result, as will be shown below, that these disadvantages are removed.

Thus in one embodiment the differential pressure may be controlled such that the pressure of the non-reactive gas is greater than the pressure in the chamber. The step of controlling the differential pressure may include monitoring the chamber pressure; monitoring the non-reactive gas pressure and adjusting the non-reactive gas pressure in response to changes in the chamber pressure. Additionally or alternatively the step of controlling the differential pressure may be responsive to the extent of processing of the workpiece. Thus, for example, if the chamber pressure variation profile is known with time, then a suitable time based adjustment could replace actual monitoring. Preferably the differential pressure is in the range of about 130 Pa to about 4 kPa.

The maximum chamber pressure is preferably in the range of about 130 Pa to not more than 65 kPa. Preferably the maximum chamber pressure is in the range of about 1.3 kPa and not more than 13 kPa.

In any of these arrangements the step of controlling may include monitoring a process parameter and adjusting the non-reactive gas pressure in accordance with that parameter. The process parameter may be at least one of the time elapsed in the process; the chamber pressure; the flow rate of the non-reactive gas; the temperature of the workpiece or the output of a process end point monitoring device.

In a further embodiment the step of controlling may include maintaining the flow rate of the non-reactive gas at a predetermined positive value or within a predetermined range of positive values. For example the flow rate of the non-reactive gas may be controlled within the range of about 0.1 sccm to about 10 sccm. The flow rate of the non-reactive gas may be controlled in accordance with a process parameter which may be at least one of: the time elapsed in the process; the chamber pressure; the flow rate of the non-reactive gas; the temperature of the workpiece or the output process end point monitoring device.

The non-reactive gas may be one or more of the inert gases e.g. helium, neon, argon, krypton, xenon, radon or nitrogen, but may also be e.g. hydrogen depending on the chemistry involved.

The non-reactive gas may constitute a heat exchange medium between the workpiece and the support. The workpiece support temperature may be controlled.

From another aspect the invention consists in apparatus for processing a workpiece including a chamber having a processing volume, a workpiece support located in the chamber, with a support face facing the processing volume, a reactive gas inlet to the processing volume, a non-reactive gas inlet to the support face and a control system for controlling the apparatus in accordance with the methods heretobefore defined.

The apparatus may include means for clamping the workpiece to the support and that support may incorporate an electrostatic chuck. The lateral extent of the support face may be equal to or greater than the corresponding nominal dimension of a workpiece and the apparatus may further include a seal or seals to separate the process volume from that part of the support face on which the workpiece lies in use. The seal may include or be constituted by lapping, polishing or dishing of the support face or a flexible seal or O ring. A gas distribution groove may be formed in part of the support face on which the workpiece lies in use by a constant radial distance inward of the periphery of that part.

Although the invention has been defined above it is to be understood it includes any inventive combination of the features set out above or in the following description.

### BRIEF DESCRIPTION OF THE DRAWINGS

The invention may be performed in various ways and specific embodiments are described in connection with the accompanying drawings, in which:

FIG. 1 is a schematic view of prior art arrangement;

FIGS. 2(a) and (b) illustrate graphically pressure regimes which can exist in the apparatus of FIG. 1;

FIG. 3 is a schematic view of an embodiment of the invention;

FIG. 4 illustrates the pressure regime within the apparatus of FIG. 3;

FIG. 5 is an enlarged schematic view of the workpiece support of the apparatus of FIG. 3 with a workpiece mounted thereon; and

FIG. 6 is a schematic view of the workpiece support of the apparatus of FIG. 3 with workpiece and seal.

### DETAILED DESCRIPTION OF THE PREFERRED EMBODIMENTS

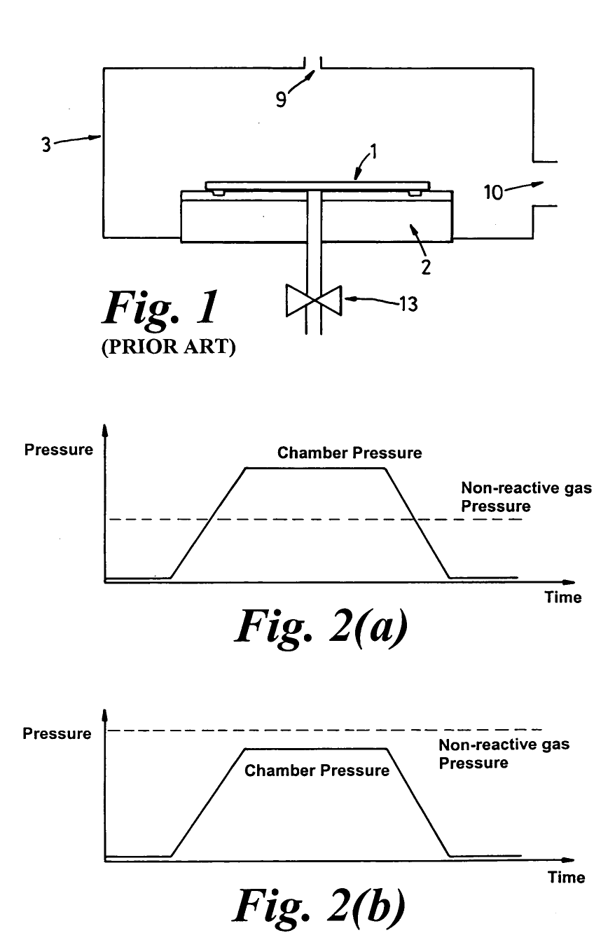

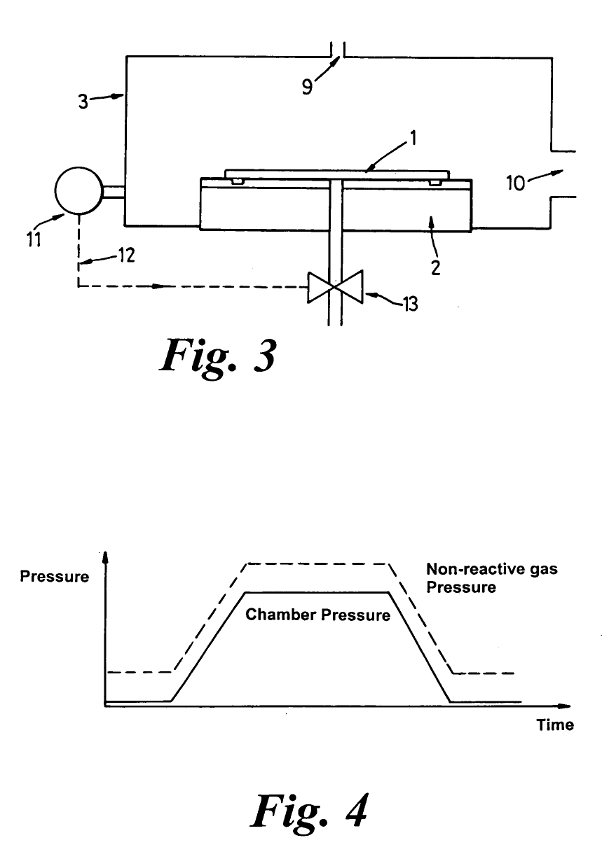

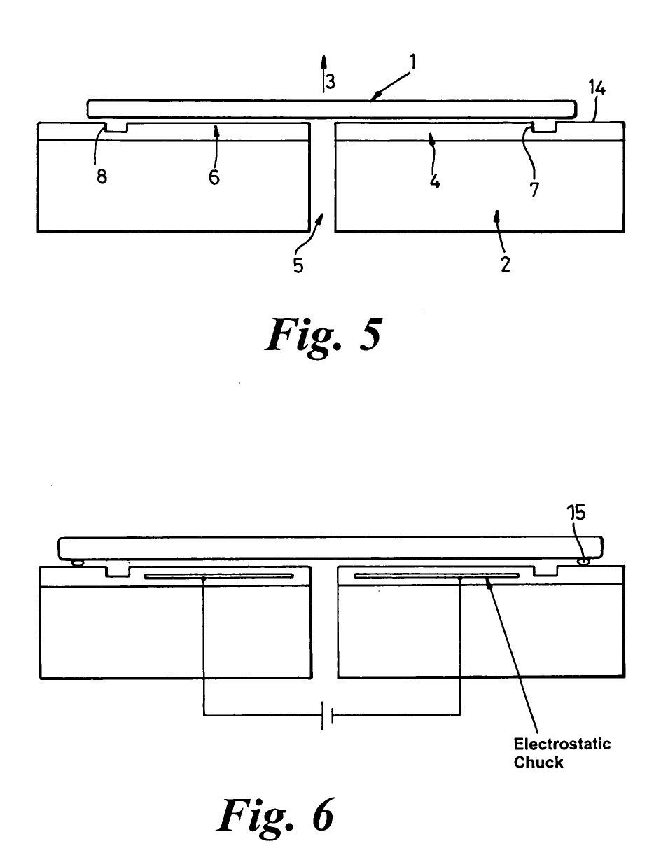

The prior art apparatus of FIG. 1 has already been described above. FIG. 3 illustrates an embodiment of apparatus incorporating one approach of the applicants' invention. Here it will be seen that a chamber pressure gauge 11 is added to the apparatus of FIG. 1. This produces a control signal on line 12, which is used to control the non-reactive gas pressure valve 13. In this most simplistic version, the gas flow through 13 is varied directly with the chamber pressure so as to cause the non-reactive gas pressure beneath the workpiece 1 substantially to track the chamber pressure, as illustrated in FIG. 4, and thereby to maintain the differential pressure within a predetermined range. This may be carried out by measuring the chamber pressure at a certain frequency and using these measures as set points for the pressure beneath the workpiece to exceed by a predetermined and/or programmable amount. It is also to be understood that there will be a pressure differential between any pressure measuring device and the space immediately behind the work piece as gas conductance is poor. An offset to take this into account may also be used. For most purposes this control of the set pressure of the non-reactive gas will suffice, but it will be understood that another approach would be to monitor the pressure beneath the workpiece support directly and to provide both pressure gauge output signals to a comparator, which would provide a control signal for the valve 13. Additionally or alternatively the flow rate of the non-reactive gas may be controlled directly, without utilising a measurement of the chamber pressure. Additionally or alternatively control can be achieved by monitoring process parameters, such as the time elapsed, the chamber pressure, the flow rate of the non-reactive gas, the temperature of the workpiece or the output of a process end point monitoring device. As the chamber pressure profile for any particular process will be substantially repeatable, varying the flow rate through the valve 13 with time may in many instances achieve the kind of pressure differential that is illustrated in FIG. 4.

Helium is the generally preferred non-reactive gas, as it has both high diffusivity and a high thermal conductivity enabling it to act as an effective heat conducting medium between the workpiece 1 and the workpiece support 2. It will be appreciated, however, that any gas that does not chemically interact with the material of the workpiece or With the etchant gas and does not cause deposition of material onto the workpiece may be chosen as the non-reactive gas.

It is also preferred that the workpiece support face 14 has a lateral dimension which is at least equal to the workpiece support so that the workpiece 1 and support 2 are close to each other around the entire circumference of the backside of the workpiece. It will be noted in FIG. 4 that a gas distribution groove 7 is provided to extend adjacent and just inside the outer periphery of the workpiece support 2 so as to ensure a good supply of gas to the gap between the support 2 and the workpiece 1 at the periphery. It also helps to-ensure that the outward flow of gas into the process chamber is essentially uniform at all points on the periphery of the workpiece. Conveniently the supply channel 5 is connected to the groove 7 by radiating channels in the workpiece support 2. As an alternative construction these channels may constitute the gas distribution system and in either case a workpiece lifting mechanism may be integrated with the gas delivery channels.

This is not to limit the invention as any gas channel or distribution may be used including porous layers and channels formed by spacings between component parts.

Additional measures may be taken as illustrated in FIG. 6 to enhance the gas seal at the edge of the area between the workpiece 1 and the workpiece support 2. These will further restrict the penetration of reactive gas into the space between them, whilst reducing the necessary leakage of non-reactive gas into the reaction chamber. Seal enhancement may include any one or more of lapping or polishing of the face 14, the introduction of a flexible sealing material or O ring (15) or, in conjunction with clamping measures described below, dishing of the surface of the workpiece support to concentrate the pressure of contact between it and the workpiece to the neighbourhood of the edge of the workpiece.

The wafer 1 may be mechanically clamped to the support 2, but it is preferred that the support 2 is in the form of an electrostatic chuck. The chuck may also include a temperature control feature as known in the art and it will be appreciated that the non-reactive gas may perform the additional function of a heat conducting medium allowing control of the temperature of the workpiece.

It is considered that the preferred differential pressure will lie in the range from at least about 130 Pa, to ensure a steady flow of gas, to not more than 4 kPa, which is the pressure at which a failure of clamping between the workpiece and the workpiece support will generally be expected with an electrostatic chuck. The precise range will vary according with the set up and the efficiency of the clamping achieved.

1. A method of processing a workpiece in a chamber with a reactive gas supplied to the chamber creating a chamber pressure including:
positioning the workpiece on a support in the chamber with a first face exposed to the reactive gas;
supplying a non-reactive gas between the support and a second face of the workpiece; and
controlling the differential gas pressure across the thickness of the workpiece.

2. A method as claimed in claim 1 wherein the differential pressure is controlled such that the pressure of non-reactive gas is always greater than the pressure in the chamber but does not exceed a limit determined by the operator.

3. A method as claimed in claim 1 wherein the step of controlling the differential pressure includes monitoring the chamber pressure; monitoring the non-reactive gas pressure and adjusting the non-reactive gas pressure in response to changes in the chamber pressure.

4. A method of processing a workpiece as claimed in claim 1 wherein the differential pressure is prevented from exceeding the pressure of attachment of the workpiece to the workpiece support.

5. A method as claimed in claim 3 wherein the step of controlling the differential pressure is responsive to the extent of processing of the workpiece.

6. A method as claimed in claim 4 wherein the step of controlling the differential pressure is responsive to the extent of processing of the workpiece.

7. A method as claimed in claim 1 wherein the differential pressure is in the range about 130 Pa to about 4 kPa.

8. A method as claimed in claim 1 wherein the step of controlling includes monitoring a process parameter and adjusting the non-reactive gas pressure in accordance with that parameter.

9. A method as claimed in claim 8 wherein the process parameter is at least one of: the time elapsed in the process; the chamber pressure; the flow rate of the non-reactive gas; the temperature of the workpiece or the output of a process end point monitoring device.

10. A method as claimed in claim 1 wherein the step of controlling includes maintaining the flow rate of the non-reactive gas at a predetermined positive value or within a predetermined range of positive valves.

11. A method as claimed in claim 10 wherein the flow rate of the non-reactive gas is controlled within the range about 0.1 sccm to about 10 sccm.

12. A method as claimed in claim 10 wherein the step of controlling includes controlling the flow rate of the non-reactive gas in accordance with a process parameter.

13. A method as claimed in claim 12 wherein the process parameter is at least one of: the time elapsed in the process; the chamber pressure; the flow rate of the non-reactive gas; the temperature of the workpiece or the output of a process end point monitoring device.

14. A method as claimed in claim 1 wherein the maximum chamber pressure is in the range of about more than about 130 Pa and not more than 65 kPa.

15. A method as claimed in claim 14 wherein the maximum chamber pressure is in the range and more than about 1.3 kPa and not more than about 13 kPa.

16. A method as claimed in claim 1 wherein the non-reactive gas is one or more of: helium, neon, argon, krypton, xenon, radon or nitrogen or hydrogen.

17. A method as claimed claim 1 wherein the non-reactive gas acts as a heat-exchange medium between the workpiece and the support.

18. A method as claimed in claim 1 wherein the workpiece support temperature is controlled.

19. Apparatus for processing a workpiece including a chamber having a processing volume, a workpiece support located in the chamber, with a support face facing the processing volume, a reactive gas inlet to the processing volume, a non-reactive gas inlet to the support face and a control system for controlling the apparatus in accordance with the method of claim 1.

20. An apparatus as claimed in claim 19 including means for clamping the workpiece to the support.

21. Apparatus as claimed in claim 19 wherein the support incorporates an electrostatic chuck.

22. Apparatus as claimed in claim 19 wherein the lateral extent of the support face is equal to or greater than the corresponding nominal dimension of a workpiece.

23. Apparatus as claimed in claim 19 further including a seal or seals to separate the process volume from that part of the support face on which a workpiece lies in use.

24. Apparatus as claimed in claim 23 wherein the seal includes or is constituted by lapping, polishing or dishing of the support face or a flexible seal or O-ring.

25. Apparatus as claimed in any one of claim 19 including a gas distribution groove formed in the part of the support face on which a workpiece lies in use and being a constant radial distance inward of the periphery of that part.
